(19) United States
(12) Patent Application Publication
(10) Pub. No.: US 2023/0420249 A1
(43) Pub. Date: Dec. 28, 2023

(54) FILM FORMING METHOD

(71) Applicant: Tokyo Electron Limited, Tokyo (JP)

(72) Inventors: Shota CHIDA, Yamanashi (JP); Yosuke WATANABE, Yamanashi (JP); Keisuke SUZUKI, Yamanashi (JP)

(21) Appl. No.: 18/333,724

(22) Filed: Jun. 13, 2023

(30) Foreign Application Priority Data
Jun. 23, 2022 (JP) 2022-100955

(51) Int. Cl. H01L 21/02; C23C 16/455; C23C 16/44

(52) U.S. Cl. CPC H01L 21/0228; H01L 21/02123; H01L 21/02178; C23C 16/45544; C23C 16/45527; C23C 16/4408

(57) ABSTRACT

A film forming method of forming a metal-containing film on a substrate, the film forming method comprising: a) supplying a metal-containing gas to the substrate; b) supplying a reactive gas to the substrate, the reactive gas being reactive with the metal-containing gas; and c) supplying a first gas to the substrate, the first gas containing a halogen gas, a hydrogen halide gas, or both.

### CROSS-REFERENCE TO RELATED APPLICATIONS

This application is based upon and claims priority to Japanese Patent Application No. 2022-100955, filed on Jun. 23, 2022, the entire contents of which are incorporated herein by reference.

### BACKGROUND

### 1. Field of the Invention

The present disclosure relates to film forming methods.

### 2. Description of the Related Art

As an example, Japanese Laid-Open Patent Publication No. 2009-260151 proposes a technique of forming a metal-doped layer by performing an insulating layer-forming step and a metal layer-forming step repeatedly and alternatingly in a manner that the metal layer-forming step is performed at least once.

### SUMMARY

According to one aspect of the present disclosure, a film forming method forms a metal-containing film on a substrate. The film forming method includes: supplying a metal-containing gas to the substrate; supplying a reactive gas to the substrate, the reactive gas being reactive with the metal-containing gas; and supplying a first gas to the substrate, the first gas containing a halogen gas, a hydrogen halide gas, or both.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a flow chart illustrating a film forming method according to a first example of embodiments;

FIG. 2A is a cross-sectional view in relation to the film forming method according to the first example of the embodiments;

FIG. 2B is a cross-sectional view in relation to the film forming method according to the first example of the embodiments;

FIG. 3 is a flow chart illustrating one example of formation of a metal-containing film;

FIG. 4 is a flow chart illustrating a film forming method according to a second example of the embodiments;

FIG. 5A is a cross-sectional view in relation to the film forming method according to the second example of the embodiments;

FIG. 5B is a cross-sectional view in relation to the film forming method according to the second example of the embodiments;

FIG. 5C is a cross-sectional view in relation to the film forming method according to the second example of the embodiments;

FIG. 5D is a cross-sectional view in relation to the film forming method according to the second example of the embodiments;

FIG. 5E is a cross-sectional view in relation to the film forming method according to the second example of the embodiments;

FIG. 6 is a flow chart illustrating one example of formation of a silicon-containing film;

FIG. 7 is a film forming apparatus according to embodiments; and

FIG. 8 is a graph illustrating measurement results of an aluminum concentration.

### DETAILED DESCRIPTION

The present disclosure provides a technique that is capable of controlling the concentration of a metal contained in a metal-containing film.

Hereinafter, non-limiting embodiments of the present disclosure will be described with reference to the drawings. In the drawings, the same or corresponding members or components are designated by the same reference symbols, and duplicate description thereof will be omitted.

### Film Forming Method

### First Example

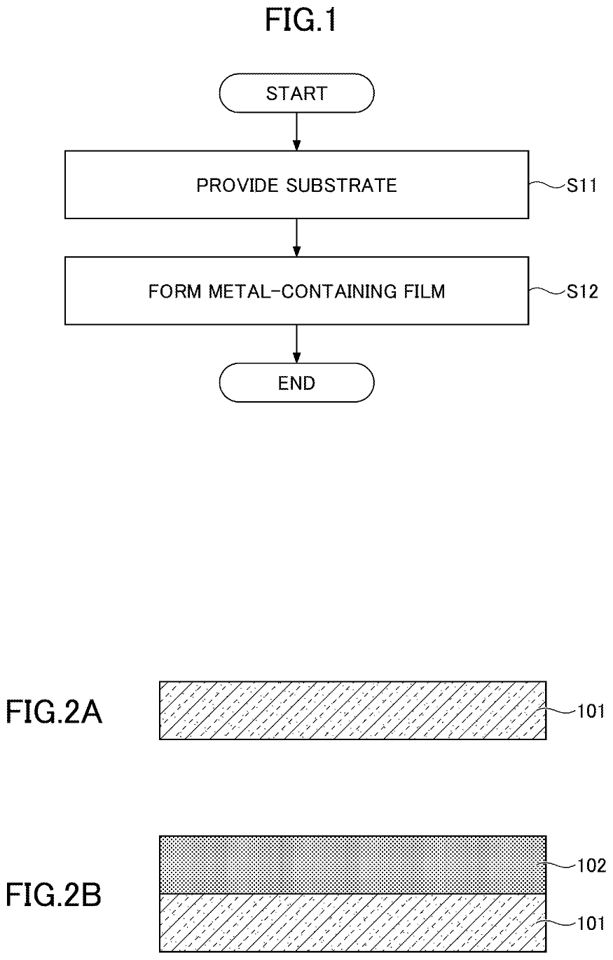

Referring to FIG. 1 to FIG. 3, the film forming method according to the first example of the embodiments will be described. The film forming method according to the first example of the embodiments includes steps S11 and S12 as illustrated in FIG. 1.

In step S11, as illustrated in FIG. 2A, a substrate 101 is provided. The substrate 101 may be, for example, a silicon wafer. On the substrate 101, an underlying film such as an insulating film (not illustrated) may be formed.

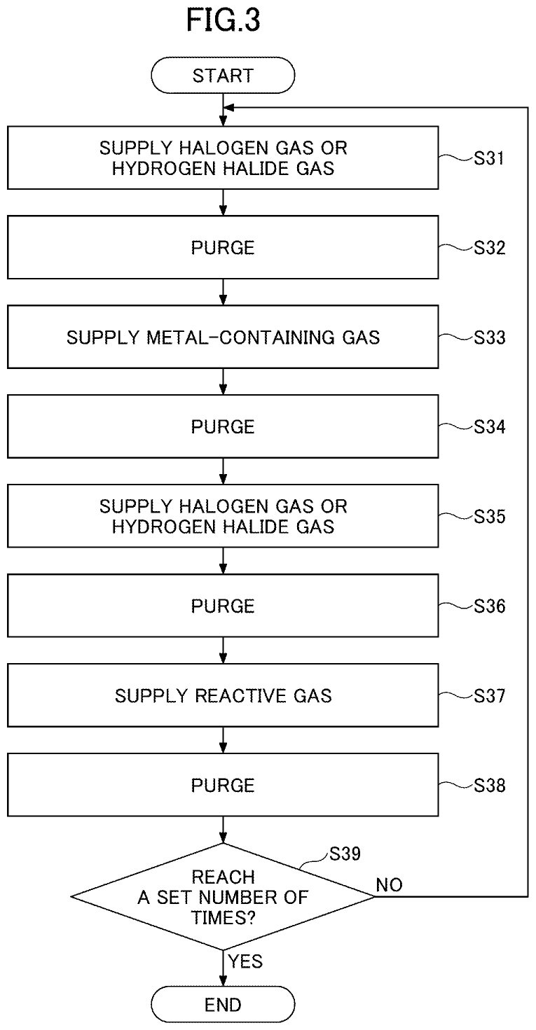

Step S12 is performed after step S11. In step S12, as illustrated in FIG. 2B, a metal-containing film 102 is formed on the substrate 101. Step S12 is performed by, for example, placing the substrate 101 in a process chamber reduced in pressure and heating the substrate 101 to a film-forming temperature. The film-foaming temperature is, for example, from 500° C. through 700° C. Step S12 includes, for example, steps S31 to S39 as illustrated in FIG. 3.

In step S31, a halogen gas or a hydrogen halide gas is supplied to and adsorbed onto the substrate 101. The halogen gas or the hydrogen halide gas adsorbed onto the substrate 101 has a function of reducing adsorption sites for the metal-containing gas. In step S31, the halogen gas and the hydrogen halide gas may be supplied to the substrate 101. As the halogen gas, for example, a chlorine gas, a bromine gas, an iodine gas, or any combination thereof may be used. As the hydrogen halide gas, for example, a hydrogen chloride gas, a hydrogen bromide gas, a hydrogen iodide gas, or any combination thereof may be used.

In step S32, a purge gas is supplied to the substrate 101, thereby exhausting the halogen gas or the hydrogen halide gas remaining on the substrate 101 without being adsorbed onto the substrate 101. As the purge gas, for example, an inert gas such as a nitrogen gas or an argon gas can be used.

In step S33, the metal-containing gas is supplied to and adsorbed onto the substrate 101. At this time, the adsorption sites on the substrate 101 are reduced by virtue of the halogen gas or the hydrogen halide gas adsorbed onto the substrate 101. Therefore, as compared with the case in which the halogen gas or the hydrogen halide gas is not adsorbed onto the substrate 101, the amount of the metal-containing gas to be adsorbed onto the substrate 101 can be reduced. As the metal-containing gas, it is possible to use, for example, one or more gases selected from the group consisting of trimethyl aluminum (TMA), copper(hexafluoroacetylacetonate)trimethylvinylsilane (Cu(hfac)TMVS), Cu(EDMDD)₂, tertiary butylimido-tris-diethylamido-tantalum (TBTDET), pentaethoxy tantalum (PET), titanium tetrachloride (TiCl₄), aluminum chloride (AlCl₃), tetrakis(ethoxy) hafnium (TEH), Zr(OtBt)₄, hafnium tetra-tertiary-butoxide (HTTB), tetrakis(dimethylamino)hafnium (TDMAH), tetrakis(diethylamino)hafnium (TDEAH), tetrakis(ethylmethylamino)hafnium (TEMAH), tetrakis(methoxymethylpropoxy)hafnium (Hf(MMP)₄), zirconium tetratertiary butoxide (ZTTB), tetrakis(dimethylamino)zirconium (TDMAZ), tetrakis(diethylamino)zirconium (TDEAZ), tetrakis(ethylmethylamino)zirconium (TEMAZ), tetrakis(methoxymethylpropoxy) zirconium (Zr(MMP)₄), tetraethyl aluminum (TEA), and tris(methoxymethylpropoxy) aluminum (Al(MMP)₃).

In step S34, a purge gas is supplied to the substrate 101, thereby exhausting the metal-containing gas remaining on the substrate 101 without being adsorbed onto the substrate 101. As the purge gas, for example, a gas the same as the purge gas in step S32 can be used.

In step S35, the halogen gas or the hydrogen halide gas is supplied to the substrate 101. The halogen gas or the hydrogen halide gas reacts with the metal-containing gas adsorbed onto the substrate 101, thereby forming a metal halide. Since the metal halide has a high saturated vapor pressure, the metal halide vaporizes and is readily released from the substrate 101. Therefore, it is possible to reduce the amount of the metal-containing gas adsorbed onto the substrate 101. In step S35, the halogen gas and the hydrogen halide gas may be supplied to the substrate 101. As the halogen gas, for example, a gas the same as the halogen gas in step S31 can be used. As the hydrogen halide gas, for example, a gas the same as the hydrogen halide gas in step S31 can be used.

In step S36, a purge gas is supplied to the substrate 101, thereby exhausting the halogen gas or the hydrogen halide gas remaining on the substrate 101 without being adsorbed onto the substrate 101. In step S36, the metal halide famed in step S35 is also exhausted. As the purge gas, for example, a gas the same as the purge gas in step S32 can be used.

In step S37, a reactive gas that is reactive with the metal-containing gas is supplied to the substrate 101, thereby forming a reaction product between the metal-containing gas and the reactive gas. In step S37, a plasma may be formed from the reactive gas. As the reactive gas, for example, a nitriding gas, an oxidizing gas, or a combination thereof can be used. For example, when a nitriding gas is used as the reactive gas, a metal nitride is formed as the reaction product. For example, when an oxidizing gas is used as the reactive gas, a metal oxide is formed as the reaction product. For example, when a nitriding gas and an oxidizing gas are used as the reactive gas, a metal oxynitride is formed as the reaction product. As the nitriding gas, for example, an ammonia (NH₃) gas, a diazene (N₂H₂) gas, a hydrazine (N₂H₄) gas, a monomethyl hydrazine (CH₃(NH)NH₂) gas, or any combination thereof can be used. As the oxidizing gas, for example, an oxygen (O₂) gas, an ozone (O₃) gas, water vapor (H₂O), a hydrogen peroxide (H₂O₂) gas, or any combination thereof can be used.

In step S38, a purge gas is supplied to the substrate 101, thereby exhausting the reactive gas remaining without being reacted with the metal-containing gas. As the purge gas, for example, a gas the same as the purge gas in step S32 can be used.

In step S39, it is determined whether steps S31 to S38 have been performed a set number of times. When steps S31 to S38 have not been performed a set number of times (i.e., “NO” in step S39), steps S31 to S38 are performed again. Whereas, when steps S31 to S38 have been performed a set number of times (i.e., “YES” in step S39), a series of the steps is ended because a film thickness of the metal-containing film 102 has reached the target thickness. In this way, by repeating an atomic layer deposition (ALD) cycle of steps S31 to S38 until the cycle has been performed a set number of times, the metal-containing film 102 is formed on the substrate 101, as illustrated in FIG. 2B. The metal-containing film 102 is used as, for example, a charge trapping layer of a three-dimensional NAND flash memory or a hard mask layer in a semiconductor process. The set number of times in step S39 is set in accordance with the target film thickness of the metal-containing film 102. The set number of times in step S39 may be once or a plurality of times.

According to the above-described film foaming

method according to the first example of the embodiments, before the metal-containing gas is supplied to the substrate 101, the halogen gas or the hydrogen halide gas is supplied to the substrate 101, thereby adsorbing the halogen gas or the hydrogen halide gas onto the substrate 101. By the halogen gas or the hydrogen halide gas adsorbed onto the substrate 101, the adsorption sites on the substrate 101 are reduced. In this state, the metal-containing gas is supplied onto the substrate 101. Therefore, as compared with the case in which the halogen gas or the hydrogen halide gas is not adsorbed onto the substrate 101, the amount of the metal-containing gas to be adsorbed onto the substrate 101 can be reduced.

Also, according to the film forming method according to the first example of the embodiments, after the metal-containing gas is supplied to the substrate 101, the halogen gas or the hydrogen halide gas is supplied to the substrate 101. The halogen gas or the hydrogen halide gas reacts with the metal-containing gas adsorbed onto the substrate 101, thereby forming a metal halide. Since the metal halide has a high saturated vapor pressure, the metal halide vaporizes and is readily released from the substrate 101. Therefore, it is possible to reduce the amount of the metal-containing gas adsorbed onto the substrate 101.

In the example as illustrated in FIG. 3, the halogen gas or the hydrogen halide gas is supplied before and after the metal-containing gas is supplied. However, this is not limiting. In one example, the halogen gas or the hydrogen halide gas may be supplied only before the metal-containing gas is supplied, and the halogen gas or the hydrogen halide gas may not be supplied after the metal-containing gas is supplied. In other words, step S35 and step S36 may be omitted. In another example, the halogen gas or the hydrogen halide gas may be supplied only after the metal-containing gas is supplied, and the halogen gas or the hydrogen halide gas may not be supplied before the metal-containing gas is supplied. In other words, step S31 and step S32 may be omitted.

In the example as illustrated in FIG. 3, only the purge gas is supplied to the substrate 101 in step S32 and step S34. However, this is not limiting. In one example, the halogen gas or the hydrogen halide gas as well as the purge gas may be supplied to the substrate 101 in step S32, step S34, or both. In this case, step S31, step S35, or both may be omitted.

### Second Example

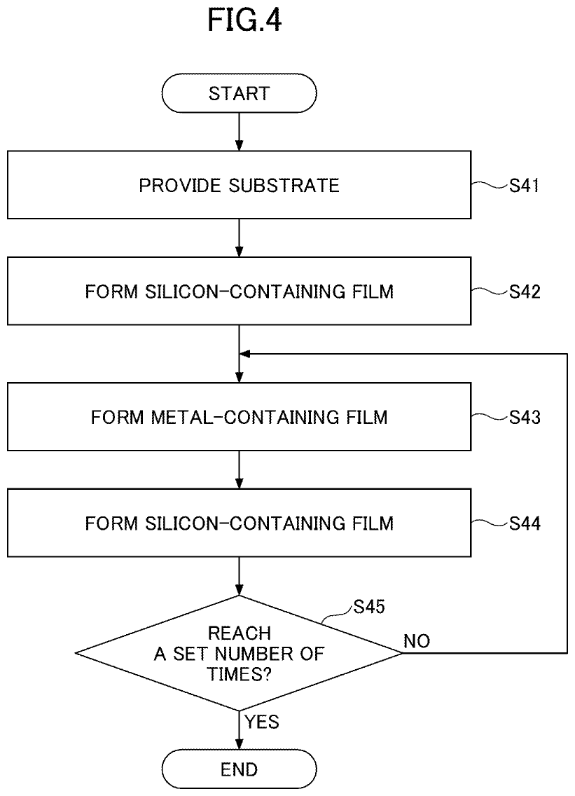

Referring to FIG. 4 to FIG. 6, the film forming method according to the second example of the embodiments will be described. The film forming method according to the second example of the embodiments includes steps S41 to S45.

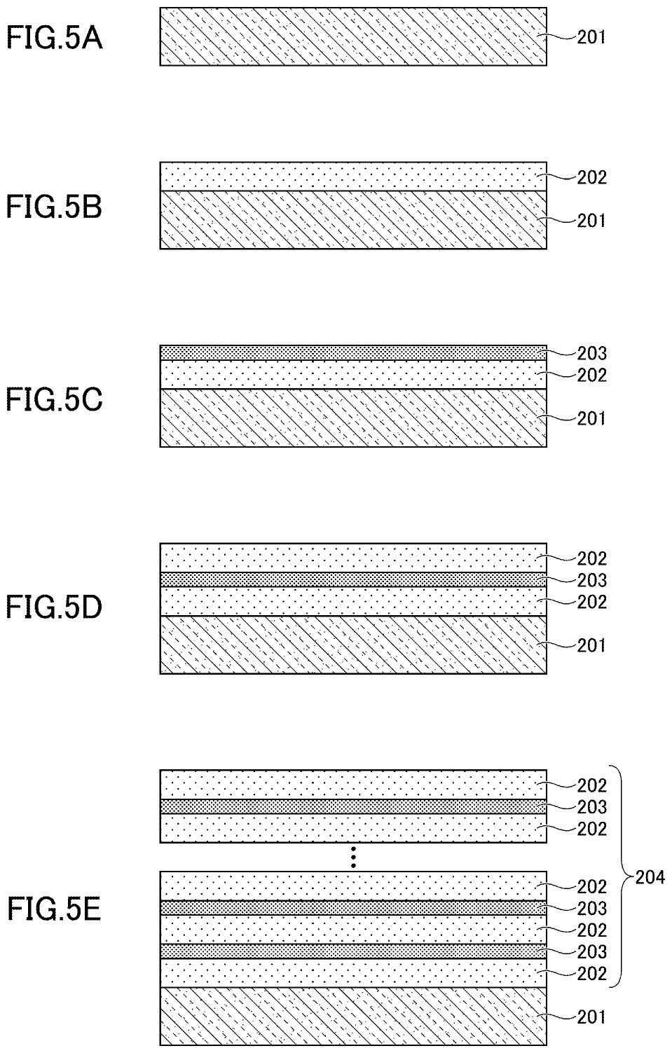

In step S41, as illustrated in FIG. 5A, a substrate 201 is provided. The substrate 201 may be, for example, a silicon wafer. On the substrate 201, an underlying film such as an insulating film (not illustrated) may be formed.

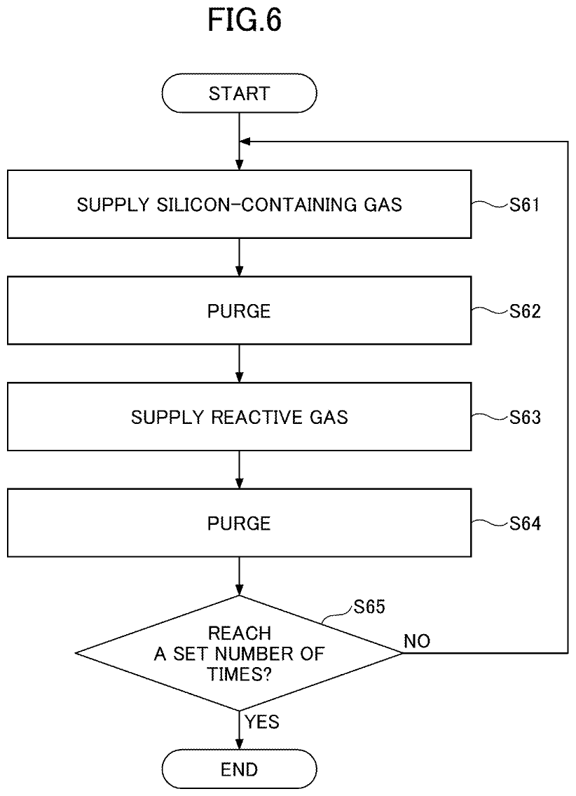

Step S42 is performed after step S41. In step S42, as illustrated in FIG. 5B, a silicon-containing film 202 is formed on the substrate 201. Step S42 is, for example, performed by placing the substrate 201 in a process chamber reduced in pressure and heating the substrate 201 to a film-forming temperature. The film-forming temperature is, for example, from 500° C. through 700° C. Step S42 includes, for example, steps S61 to S65 as illustrated in FIG. 6.

In step S61, a silicon containing gas is supplied to and adsorbed onto the substrate 201. As the silicon containing gas, it is possible to use, for example, one or more gases selected from the group consisting of dichlorosilane (DCS), tetraethoxysilane (TEOS), tetramethylsilane hexachlorodisilane (HCD), monosilane [SiH₄], disilane [Si₂H₆], hexamethyldisilazane (HMDS), trichlorosilane (TCS), disilylamine (DSA), trisilylamine (TSA), bis(tertiary-butylamino)silane (BTBAS), tris(dimethylamino)silane (3DMAS), tetrakis(dimethylamino)silane (4DMAS), tris(ethylmethylamino)silane (TEMASiH), tetrakis(ethylmethylamino)silane (TEMASi), and tetrakis(methoxymethylpropoxy)silane (Si(MMP)₄).

In step S62, a purge gas is supplied to the substrate 201, thereby exhausting the silicon containing gas remaining on the substrate 201 without being adsorbed onto the substrate 201. As the purge gas, for example, a gas the same as the purge gas in step S32 can be used.

In step S63, a reactive gas that is reactive with the silicon containing gas is supplied to the substrate 201, thereby forming a reaction product between the silicon containing gas and the reactive gas. In step S63, a plasma may be formed from the reactive gas. As the reactive gas, for example, a nitriding gas, an oxidizing gas, or a combination thereof can be used. For example, when a nitriding gas is used as the reactive gas, a silicon nitride is formed as the reaction product. For example, when an oxidizing gas is used as the reactive gas, a silicon oxide is formed as the reaction product. For example, when a nitriding gas and an oxidizing gas are used as the reactive gas, a silicon oxynitride is formed as the reaction product. As the nitriding gas, for example, a gas the same as the nitriding gas in step S37 can be used. As the oxidizing gas, for example, a gas the same as the oxidizing gas in step S37 can be used.

In step S64, a purge gas is supplied to the substrate 201, thereby exhausting the reactive gas remaining without being reacted with the silicon containing gas. As the purge gas, for example, a gas the same as the purge gas in step S32 can be used.

In step S65, it is determined whether steps S61 to S64 have been performed a set number of times. When steps S61 to S64 have not been performed a set number of times (i.e., “NO” in step S65), steps S61 to S64 are performed again. Whereas, when steps S61 to S64 have been performed a set number of times (i.e., “YES” in step S65), a series of the steps is ended because a film thickness of the silicon-containing film 202 has reached the target thickness. In this way, by repeating an atomic layer deposition (ALD) cycle of steps S61 to S64 until the cycle has been performed a set number of times, as illustrated in FIG. 5B, the silicon-containing film 202 is formed on the substrate 201. The set number of times in step S65 is set in accordance with the target film thickness of the silicon-containing film 202. The set number of times in step S65 may be once or a plurality of times.

Step S43 is performed after step S42. In step S43, as illustrated in FIG. 5C, a metal-containing film 203 is formed on the silicon-containing film 202. Step S43 is, for example, performed by placing the substrate 201 in a process chamber reduced in pressure and heating the substrate 201 to a film-forming temperature. The film-foaming temperature is, for example, from 500° C. through 700° C. Step S43 is, for example, continuously performed in the same process chamber as the process chamber in which step S42 is performed. In this case, the substrate is not transferred to a different process chamber, and the time required for transferring the substrate can be saved. Step S43 may be, for example, performed in a different process chamber from the process chamber in which step S42 is performed. When the film-forming temperature in step S42 is different from the film-foaming temperature in step S43, it is possible to shorten the time required for changing the film-forming temperature by performing step S43 in a different process chamber from the process chamber in which step S42 is performed. Step S43 may be, for example, the same as step S12, including steps S31 to S39 as illustrated in FIG. 3.

Step S44 is performed after step S43. In step S44, as illustrated in FIG. 5D, the silicon-containing film 202 is formed on the metal-containing film 203. Step S44 may be, for example, the same as step S42, including steps S61 to S65 as illustrated in FIG. 6.

In step S45, it is determined whether steps S43 and S44 have been performed a set number of times. When steps S43 and S44 have not been performed a set number of times (i.e., “NO” in step S45), steps S43 and S44 are performed again. Whereas, when steps S43 and S44 have been performed a set number of times (i.e., “YES” in step S45), a series of the steps is ended because a stacked number of the silicon-containing film 202 and the metal-containing film 203 has reached the target stacked number. In this way, by repeating a stacking cycle of steps S43 and S44 until the stacking cycle has been performed a set number of times, a stacked film 204 of the silicon-containing film 202 and the metal-containing film 203 is formed on the substrate 201, as illustrated in FIG. 5E. For example, the stacked film 204 includes, as illustrated in FIG. 5E, the silicon-containing film 202 at a position the closest to the substrate 201. For example, the stacked film 204 includes, as illustrated in FIG. 5E, the silicon-containing film 202 at a position the farthest from the substrate 201. The stacked film 204 can be a metal-doped silicon-containing film as a whole, by the metal in the metal-containing film 203 being diffused toward and added (doped) to the silicon-containing film, for example, in accordance with a temperature during the film formation or a heating process in the subsequent steps. The stacked film 204 is used as, for example, a charge trapping layer of a three-dimensional NAND flash memory or a hard mask layer in a semiconductor process. The set number of times in step S45 is set in accordance with the target film thickness of the stacked film 204. The set number of times in step S45 may be once or a plurality of times.

According to the above-described film foaming method according to the second example of the embodiments, before the metal-containing gas is supplied to the substrate 201, the halogen gas or the hydrogen halide gas is supplied to the substrate 201, thereby adsorbing the halogen gas or the hydrogen halide gas onto the substrate 201. Therefore, similar to the film forming method according to the first example of the embodiments, as compared with the case in which the halogen gas or the hydrogen halide gas is not adsorbed onto the substrate 201, the amount of the metal-containing gas to be adsorbed onto the substrate 201 can be reduced.

Also, according to the film forming method according to the second example of the embodiments, after the metal-containing gas is supplied to the substrate 201, the halogen gas or the hydrogen halide gas is supplied to the substrate 201. Therefore, similar to the film foaming method according to the first example of the embodiments, it is possible to reduce the amount of the metal-containing gas adsorbed onto the substrate 201.

### Film Forming Apparatus

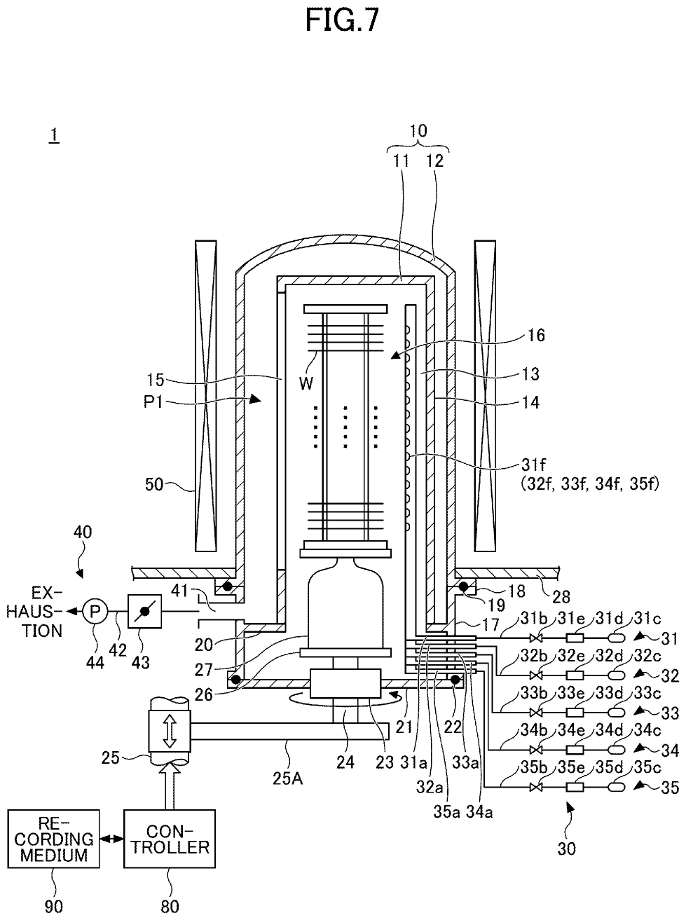

Referring to FIG. 7, a film forming apparatus 1 according to the embodiments will be described. As illustrated in FIG. 7, the film forming apparatus 1 is a batch-type apparatus configured to perform a process to a plurality of substrates W all at once.

The film forming apparatus 1 includes a process chamber 10, a gas supply 30, an exhauster 40, a heater 50, and a controller 80.

The process chamber 10 can be reduced in internal pressure and is configured to house the substrates W. The process chamber 10 includes: a cylindrical inner tube 11 that includes the ceiling and is opened at the bottom end thereof; and a cylindrical outer tube 12 that includes the ceiling, is opened at the bottom end thereof, and surrounds the outer surface of the inner tube 11. The inner tube 11 and the outer tube 12 are formed of a heat-resistant material such as quartz. The inner tube 11 and the outer tube 12 form a dual-tube structure in which the inner tube 11 and the outer tube 12 are disposed approximately coaxially.

The ceiling of the inner tube 11 may be, for example, flat. Around an inner side wall of the inner tube 11, a housing 13 configured to house gas nozzles is formed along a longitudinal direction (up-and-down direction) of the inner tube 11. For example, the side wall of the inner tube 11 is partially projected outward to foam a projection 14, and the inner space of the projection 14 is formed as the housing 13.

In the opposite side wall of the inner tube 11, a rectangular opening 15 is formed to face the housing 13 along a longitudinal direction (up-and-down direction) of the inner tube 11.

The opening 15 is a gas exhaustion port that is formed so that a gas in the inner tube 11 can be exhausted therethrough. The opening 15 is formed such that the length of the opening 15 is the same as the length of a boat 16 or such that the opening 15 extends in an up-and-down direction so as to have a length longer than that of the boat 16.

The bottom end of the process chamber 10 is supported by a cylindrical manifold 17. The manifold 17 is famed of, for example, stainless steel. At the top end of the manifold 17, a flange 18 is formed. The flange 18 supports the bottom end of the outer tube 12. Between the flange 18 and the bottom end of the outer tube 12, a seal member 19 such as an O-ring is provided. Thereby, the inner space of the outer tube 12 is hermetically maintained.

The inner wall of an upper portion of the manifold 17 is provided with an annular support 20. The support 20 supports the bottom end of the inner tube 11.

To the opening at the bottom end of the manifold 17, a cover 21 is hermetically attached via a seal member 22 such as an O-ring. Thereby, the opening at the bottom end of the process chamber 10; i.e., the opening of the manifold 17 is hermetically sealed. The cover 21 is formed of, for example, stainless steel.

At the center of the cover 21, a penetrating rotating shaft 24 is provided via a magnetic fluid seal 23. The lower portion of the rotating shaft 24 is rotatably supported by an aim 25A of an ascending and descending mechanism 25 foamed of a boat elevator.

At the top end of the rotating shaft 24, a rotating plate 26 is provided. On the rotating plate 26, the boat 16 retaining the substrates W is placed via a warming stage 27 formed of quartz. The boat 16 is rotated by rotating the rotating shaft 24. By ascending and descending the ascending and descending mechanism 25, the boat 16 moves upward and downward together with the cover 21. Thereby, the boat 16 is inserted into and released from the process chamber 10. The boat 16 can be housed in the process chamber 10. The boat 16 approximately parallelly retains a plurality of (e.g., from 50 through 150) substrates W at intervals in an up-and-down direction.

The gas supply 30 is configured to introduce various process gases used for the above-described film forming method into the inner tube 11. The gas supply 30 includes a DCS supply 31, an aluminum chloride supply 32, an ammonia supply 33, a chlorine supply 34, and a nitrogen supply 35.

The DCS supply 31 includes: a DCS supply tube 31a inside the process chamber 10; and a DCS supply path 31b outside the process chamber 10. The DCS supply path 31b sequentially includes a DCS source 31c, a mass flow controller 31d, and a valve 31e from upstream to downstream of a gas flow direction. Thereby, a DCS gas of the DCS source 31c is controlled by the valve 31e in terms of the time of supply, and is also adjusted by the mass flow controller 31d to a predetermined flow rate. The DCS gas flows into the DCS supply tube 31a through the DCS supply path 31b, and is discharged from the DCS supply tube 31a into the process chamber 10. The DCS gas is one example of the silicon containing gas.

The aluminum chloride supply 32 includes: an aluminum chloride supply tube 32a inside the process chamber 10; and an aluminum chloride supply path 32b outside the process chamber 10. The aluminum chloride supply path 32b sequentially includes an aluminum chloride source 32c, a mass flow controller 32d, and a valve 32e from upstream to downstream of a gas flow direction. Thereby, an aluminum chloride gas of the aluminum chloride source 32c is controlled by the valve 32e in terms of the time of supply, and is also adjusted by the mass flow controller 32d to a predetermined flow rate. The aluminum chloride gas flows into the aluminum chloride supply tube 32a through the aluminum chloride supply path 32b, and is discharged from the aluminum chloride supply tube 32a into the process chamber 10. The aluminum chloride gas is one example of the metal-containing gas.

The ammonia supply 33 includes: an ammonia supply tube 33a inside the process chamber 10; and an ammonia supply path 33b outside the process chamber 10. The ammonia supply path 33b sequentially includes an ammonia source 33c, a mass flow controller 33d, and a valve 33e from upstream to downstream of a gas flow direction. Thereby, an ammonia gas of the ammonia source 33c is controlled by the valve 33e in tams of the time of supply, and is also adjusted by the mass flow controller 33d to a predetermined flow rate. The ammonia gas flows into the ammonia supply tube 33a through the ammonia supply path 33b, and is discharged from the ammonia supply tube 33a into the process chamber 10. The ammonia gas is one example of the reactive gas.

The chlorine supply 34 includes: a chlorine supply tube 34a inside the process chamber 10; and a chlorine supply path 34b outside the process chamber 10. The chlorine supply path 34b sequentially includes a chlorine source 34c, a mass flow controller 34d, and a valve 34e from upstream to downstream of a gas flow direction. Thereby, a chlorine gas of the chlorine source 34c is controlled by the valve 34e in tams of the time of supply, and is also adjusted by the mass flow controller 34d to a predetermined flow rate. The chlorine gas flows into the chlorine supply tube 34a through the chlorine supply path 34b, and is discharged from the chlorine supply tube 34a into the process chamber 10. The chlorine gas is one example of the halogen gas.

The nitrogen supply 35 includes: a nitrogen supply tube 35a inside the process chamber 10; and a nitrogen supply path 35b outside the process chamber 10. The nitrogen supply path 35b sequentially includes a nitrogen source 35c, a mass flow controller 35d, and a valve 35e from upstream to downstream of a gas flow direction. Thereby, a nitrogen gas of the nitrogen source 35c is controlled by the valve 35e in tams of the time of supply, and is also adjusted by the mass flow controller to a predetermined flow rate. The nitrogen gas flows into the nitrogen supply tube 35a through the nitrogen supply path 35b, and is discharged from the nitrogen supply tube 35a into the process chamber 10. The nitrogen gas is one example of the purge gas.

The gas supply tubes (the DCS supply tube 31a, the aluminum chloride supply tube 32a, the ammonia supply tube 33a, the chlorine supply tube 34a, and the nitrogen supply tube 35a) are fixed to the manifold 17. The gas supply tubes are formed of, for example, quartz. The gas supply tubes each extend in the form of a straight line along a vertical direction at a position near the inner tube 11, and bend in an L shape to horizontally extend in the manifold 17, thereby penetrating the manifold 17. The gas supply tubes are provided side by side along a circumferential direction of the inner tube 11. The gas supply tubes are formed at the same height.

At sites of the DCS supply tube 31a that are positioned in the inner tube 11, a plurality of DCS discharge ports 31f are provided. At sites of the aluminum chloride supply tube 32a that are positioned in the inner tube 11, a plurality of aluminum chloride discharge ports 32f are provided. At sites of the ammonia supply tube 33a that are positioned in the inner tube 11, a plurality of ammonia discharge ports 33f are provided. At sites of the chlorine supply tube 34a that are positioned in the inner tube 11, a plurality of chlorine discharge ports 34f are provided. At sites of the nitrogen supply tube 35a that are positioned in the inner tube 11, a plurality of nitrogen discharge ports 35f are provided.

The discharge ports (the DCS discharge ports 31f, the aluminum chloride discharge ports 32f, the ammonia discharge ports 33f, the chlorine discharge ports 34f, or the nitrogen discharge ports 35f) are famed at predetermined intervals along extending directions of the gas supply tubes. Each of the discharge ports releases the gas in a horizontal direction. The intervals between the discharge ports are set, for example, to the same intervals as the intervals between the substrates W retained in the boat 16. The positions of the discharge ports in a height direction are set to the middle positions between the substrates W that are next to each other in an up-and-down direction. Thereby, each of the discharge ports can efficiently supply the gas to between the substrates W that are next to each other in the up-and-down direction.

The gas supply 30 may discharge a gas mixture of two or more gases from a single supply tube. The gas supply tubes (the DCS supply tube 31a, the aluminum chloride supply tube 32a, the ammonia supply tube 33a, the chlorine supply tube 34a, and the nitrogen supply tube 35a) may be different from each other in shape and arrangement. Also, the film forming apparatus 1 may further include a supply tube for supplying another gas, in addition to the DCS gas, the aluminum chloride gas, the ammonia gas, the chlorine gas, and the nitrogen gas.

The exhauster 40 is configured to exhaust a gas that is exhausted through the opening 15 from the interior of the inner tube 11 and exhausted from a gas outlet 41 through a space P1 between the inner tube 11 and the outer tube 12. The gas outlet 41 is formed in the side wall of the upper portion of the manifold 17 and above the support An exhaustion path 42 is connected to the gas outlet 41. The exhaustion path 42 sequentially includes a pressure adjusting valve 43 and a vacuum pump 44 with a gap therebetween, and can exhaust the gas in the process chamber 10.

A heater 50 is provided around the outer tube 12. The heater 50 is provided on, for example, a base plate 28. The heater 50 has such a cylindrical shape as to cover the outer tube 12. The heater 50 includes, for example, a heat generator, and is configured to heat the substrates W in the process chamber 10.

The controller 80 is configured to control the operations of the components of the film forming apparatus 1. The controller 80 may be, for example, a computer. A program for causing the computer to execute the operations of the components of the film forming apparatus 1 is stored in a recording medium 90. The recording medium 90 may be, for example, a flexible disc, a compact disc, a hard disc, a flash memory, or a digital versatile disc (DVD).

### Operations of the Film Forming Apparatus

Operations in performing the film forming method according to the first example of the embodiments by the film forming apparatus 1 will be described.

First, the controller 80 controls the ascending and descending mechanism 25 to: transfer the boat 16, retaining a plurality of substrates W, into the process chamber 10; and hermetically seal the opening at the bottom end of the process chamber 10 with the cover 21 for hermetical closing. Each of the substrates W corresponds to the substrate 101.

Subsequently, the controller 80 controls the gas supply 30, the exhauster 40, and the heater 50 to perform step S12 so that an aluminum nitride film is formed on the substrate 101. Specifically, first, the controller 80 controls the exhauster 40 to reduce the internal pressure of the process chamber 10 to a film-forming pressure, and controls the heater 50 to adjust and maintain the substrate W to and at a film-foaming temperature. The film-foaming temperature is, for example, from 500° C. through 700° C. Next, the controller 80 controls the gas supply 30 to perform steps S31 to S38 as illustrated in FIG. 3, thereby supplying the aluminum chloride gas, the chlorine gas, the ammonia gas, and the nitrogen gas into the process chamber 10.

Subsequently, the controller 80 determines whether steps S31 to S38 have been performed a set number of times. When steps S31 to S38 have not been performed a set number of times, steps S31 to S38 are performed again.

When steps S31 to S38 have been performed a set number of times, an aluminum nitride film having the target film thickness is formed. Therefore, after the internal pressure of the process chamber 10 has been increased to the atmospheric pressure and the internal temperature of the process chamber 10 has been decreased to a dischargeable temperature, the controller 80 controls the ascending and descending mechanism 25 to discharge the boat 16 from the process chamber 10.

### EXAMPLES

In Examples, it was confirmed whether aluminum contained in an aluminum chloride gas was released by supplying a chlorine gas to a silicon wafer onto which the aluminum chloride gas had been adsorbed. The silicon wafer is one example of the substrate. The aluminum chloride gas is one example of the metal-containing gas. The chlorine gas is one example of the halogen gas.

First, the aluminum chloride gas was supplied to and adsorbed onto the silicon wafer. Subsequently, the chlorine gas was supplied to the silicon wafer onto which the aluminum chloride gas had been adsorbed. Also, before and after supplying the chlorine gas to the silicon wafer onto which the aluminum chloride gas had been adsorbed, the aluminum concentration was measured through total reflection X-ray fluorescence (TRXF).

For comparison, similar processing and measurement were performed using a nitrogen gas instead of the chlorine gas.

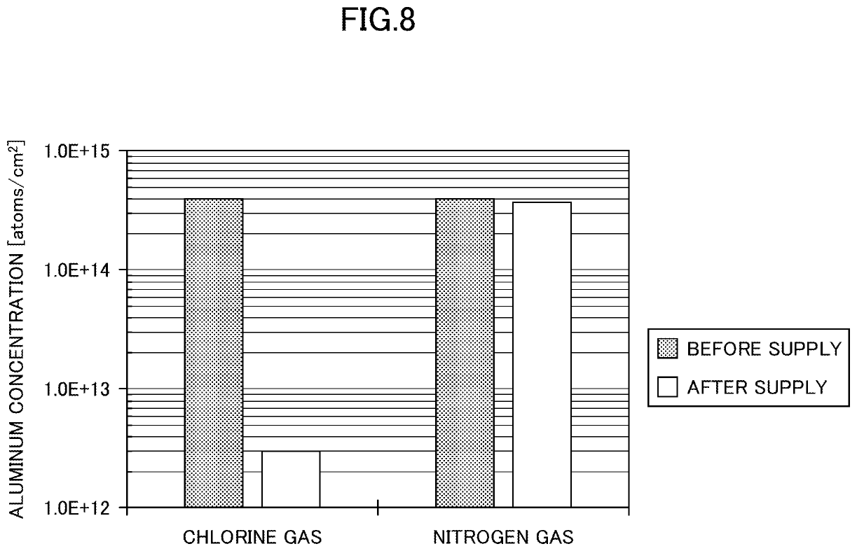

FIG. 8 is a graph illustrating the measurement results of the aluminum concentration. In FIG. 8, the left-hand two bars denote the aluminum concentrations [atoms/cm²] before and after supplying the chlorine gas to the silicon wafer onto which the aluminum chloride gas had been adsorbed. In FIG. 8, the right-hand two bars denote the aluminum concentrations [atoms/cm²] before and after supplying the nitrogen gas to the silicon wafer onto which the aluminum chloride gas had been adsorbed.

As illustrated in FIG. 8, it is found that by supplying the chlorine gas to the silicon wafer onto which the aluminum chloride gas has been adsorbed, the aluminum concentration becomes reduced by a value equivalent to about two orders of magnitude. Meanwhile, it is found that when the nitrogen gas is supplied to the silicon wafer onto which the aluminum chloride gas has been adsorbed, almost no change in the aluminum concentration is observed. These results indicate that by supplying the chlorine gas to the silicon wafer onto which the aluminum chloride gas has been adsorbed, it is possible to control the aluminum concentration.

According to the present disclosure, it is possible to control the concentration of a metal contained in a metal-containing film.

It should be understood that the embodiments disclosed herein are illustrative and not restrictive in all respects. Various omissions, substitutions, and changes may be made to the above-described embodiments without departing from the scope of claims recited and the spirit of the disclosure.

The above-described embodiments are related to the batch-type film forming apparatus configured to perform the process to the plurality of substrates all at once, but the present disclosure is not limited thereto.

For example, the film forming apparatus may be a single wafer processing apparatus configured to process a plurality of substrates one by one. For example, the film forming apparatus may be a semi-batch-type apparatus configured to perform a process to a plurality of substrates by revolving the substrates on a rotating table in a process chamber so as to sequentially pass through a plurality of processing regions.

What is claimed is:

1. A film foaming method of forming a metal-containing film on a substrate, the film forming method comprising:
a) supplying a metal-containing gas to the substrate;
b) supplying a reactive gas to the substrate, the reactive gas being reactive with the metal-containing gas; and
c) supplying a first gas to the substrate, the first gas containing a halogen gas, a hydrogen halide gas, or both.

2. A film foaming method of forming a stacked film on a substrate, the stacked film including a silicon-containing film and a metal-containing film, the film forming method comprising:
a) forming the silicon-containing film; and
b) forming the metal-containing film,
wherein the b) includes
b1) supplying a metal-containing gas to the substrate,
b2) supplying a reactive gas to the substrate, the reactive gas being reactive with the metal-containing gas, and
b3) supplying a first gas to the substrate, the first gas containing a halogen gas, a hydrogen halide gas, or both.

3. The film forming method according to claim 1, wherein the c) is performed before the a).

4. The film forming method according to claim 1, wherein the c) is performed after the a).

5. The film forming method according to claim 1, wherein the c) is performed before and after the a).

6. The film forming method according to claim 1, wherein an atomic layer deposition (ALD) cycle including at least one of the a), at least one of the b), and at least one of the c) is repeated a plurality of times.

7. The film forming method according to claim 1, wherein the metal-containing film is an aluminum nitride film.

8. The film forming method according to claim 2, wherein the b3) is performed before the b1).

9. The film forming method according to claim 2, wherein the b3) is performed after the b1).

10. The film forming method according to claim 2, wherein the b3) is performed before and after the b1).

11. The film forming method according to claim 2, wherein an atomic layer deposition (ALD) cycle including at least one of the b1), at least one of the b2), and at least one of the b3) is repeated a plurality of times.

12. The film forming method according to claim 2, wherein the metal-containing film is an aluminum nitride film.

13. The film forming method according to claim 2, wherein a stacking cycle including at least one of the a) and at least one of the b) is repeated a plurality of times.

14. The film forming method according to claim 2, wherein the stacked film includes the silicon-containing film at a position closest to the substrate.

15. The film forming method according to claim 2, wherein the stacked film includes the silicon-containing film at a position farthest from the substrate.
